(19) United States
(12) Patent Application Publication
(10) Pub. No.: US 2026/0179893 A1
(43) Pub. Date: Jun. 25, 2026

(54) MAGNETIC FIELD GENERATING APPARATUS

(71) Applicant: Samsung Electronics Co., Ltd., Suwon-si (KR)

(72) Inventors: Jeonghyoun Sung, Suwon-si (KR); Hyoungsoo Kim, Suwon-si (KR); Gihyun Song, Suwon-si (KR); Sungyeol Kim, Suwon-si (KR); Meehyun Lim, Suwon-si (KR); Sanghoon Jung, Suwon-si (KR)

(73) Assignees: Samsung Electronics Co., Ltd., Suwon-si (KR); Korea Advanced Institute of Science and Technology, Daejeon (KR)

(21) Appl. No.: 19/315,099

(22) Filed: Aug. 29, 2025

(30) Foreign Application Priority Data
Dec. 24, 2024 (KR) 10-2024-0196073

(51) Int. Cl. H01J 37/34

(52) U.S. Cl. CPC H01J 37/3405; H01J 37/3452; H01J 37/3455

(57) ABSTRACT

An example magnetic field generating apparatus includes a magnet plate, which includes a plurality of magnets arranged on an upper surface of the magnet plate, and a magnetic field shaping pipe arranged above the magnet plate, where the magnetic field shaping pipe includes a transport fluid therein, a plurality of magnetic metal droplets are arranged in the transport fluid, the plurality of magnetic metal droplets are spaced apart from each other in a horizontal direction, each of the plurality of magnetic metal droplets includes micro-magnetic particles, and the plurality of magnets are arranged such that N- and S-poles of the magnets alternately face upwards.

### CROSS-REFERENCE TO RELATED APPLICATION

This application claims priority under 35 U.S.C. § 119 to Korean Patent Application No. 10-2024-0196073, filed on Dec. 24, 2024, in the Korean Intellectual Property Office, the disclosure of which is incorporated by reference herein in its entirety.

### BACKGROUND

In various semiconductor fabrication processes (for example, deposition processes and etching processes), plasma treatment is performed on substrates. To control the density of plasma used in processes, there are increasing attempts to applying magnetic fields to plasma formation spaces. To accurately apply magnetic fields to particular target points in internal spaces of plasma chambers, complicated-structure mechanical devices (for example, driving devices for adjusting positions of solid magnets) and techniques of precisely controlling such mechanical devices may be used.

### SUMMARY

The present disclosure relates to a magnetic field generating apparatus capable of applying magnetic fields having various shapes to the internal space of a plasma chamber, and a magnetic field generating apparatus capable of preventing non-uniform erosion of a sputtering target. Implementations of the present disclosure allow magnetic fields having shapes intended by users (for example, process engineers) to be applied to target points in internal spaces of plasma chambers.

However, the present disclosure is not limited to the above aspects, and the above and other aspects of the present disclosure may be clearly understood by those of ordinary skill in the art from the following detailed description.

In some implementations, a magnetic field generating apparatus includes a magnet plate including a plurality of magnets arranged on an upper surface of the magnet plate, and a magnet field shaping pipe arranged above the magnet plate, wherein a plurality of magnetic metal droplets are arranged in the transport fluid, the plurality of magnetic metal droplets are spaced apart from each other in a horizontal direction, each of the plurality of magnetic metal droplets includes micro-magnetic particles, and the plurality of magnets are arranged such that N- and S-poles of the plurality of magnets alternately face upwards.

In some implementations, a magnetic field generating apparatus includes a magnet plate arranged behind a sputtering target and including a plurality of magnets that are arranged on an upper surface of the magnet plate, and a magnetic field shaping pipe arranged between the magnet plate and the sputtering target, wherein the magnetic field shaping pipe includes a transport fluid therein, a plurality of magnetic metal droplets are arranged in the transport fluid, the plurality of magnetic metal droplets are spaced apart from each other in a horizontal direction, each of the plurality of magnetic metal droplets includes micro-magnetic particles, and the plurality of magnets are arranged such that N- and S-poles of the plurality of magnets alternately face upwards.

In some implementations, a magnetic field generating apparatus includes a magnet plate arranged behind a sputtering target and including a plurality of magnets that are arranged on an upper surface of the magnet plate, a magnetic field shaping pipe arranged between the magnet plate and the sputtering target, and a support pin protruding from the upper surface of the magnet plate and connected to a portion of the magnetic field shaping pipe to support the magnetic field shaping pipe, wherein the magnetic field shaping pipe comprises a transport fluid therein, a plurality of magnetic metal droplets are arranged in the transport fluid, the plurality of magnetic metal droplets are spaced apart from each other in a horizontal direction, each of the plurality of magnetic metal droplets includes micro-magnetic particles, and the plurality of magnets are arranged such that N- and S-poles of the plurality of magnets alternately face upwards.

### BRIEF DESCRIPTION OF THE DRAWINGS

Implementations will be more clearly understood from the following detailed description taken in conjunction with the accompanying drawings.

FIG. 1 is a cross-sectional view of an example of a magnetic field generating apparatus.

FIG. 2 is a cross-sectional view of an example of a magnetic field generating apparatus.

FIG. 3 is a cross-sectional view of an example of a magnetic field shaping pipe.

FIG. 4 is a diagram illustrating example characteristics of a liquid metal.

FIG. 5 is a diagram illustrating an example of a method of manufacturing a magnetic liquid metal.

FIG. 6 is a cross-sectional view illustrating an example of a configuration of a magnetic metal droplet.

FIG. 7 is a cross-sectional view of an example of a magnetic field generating apparatus.

FIG. 8 is a cross-sectional view of an example of a magnetic field generating apparatus.

### DETAILED DESCRIPTION

Hereinafter, implementations of the present disclosure will be described in detail with reference to the accompanying drawings. Like components are denoted by like reference numerals throughout the specification, and repeated descriptions thereof are omitted.

Hereinafter, implementations of the present disclosure will be clearly described in detail for those of ordinary skill in the art to implement the present disclosure with ease.

In the specification, when an element is described as being “apart (or spaced apart)” and/or “isolated (or separated)” from another element in a particular direction (for example, apart from the other element in a vertical direction or a horizontal direction), it may be understood that the element is isolated (or separated) from and not in direct contact with the other element in the particular direction (for example, the element is isolated (or separated) from and not in direct contact with the other element in the vertical direction or the horizontal direction). Likewise, when elements are described as being “apart (or spaced apart)” and/or “isolated (or separated)” from each other in a particular direction (for example, apart from the other element in a vertical direction or a horizontal direction), it may be understood that the elements are isolated (or separated) from and not in direct contact with each other in the particular direction (for example, the elements are isolated (or separated) from and not in direct contact with each other in the vertical direction or the horizontal direction). Similarly, when a structure is positioned between two other structures and isolates the two other structures from each other, it may be understood that the structure isolates the two other structures from each other such that the two other structures are not in direct contact with each other.

Herein, the horizontal direction may include a first horizontal direction (an X direction) and a second horizontal direction (a Y direction) that intersect with each other. A direction, which intersects with the first horizontal direction (the X direction) and the second horizontal direction (the Y direction), may be referred as a vertical direction (a Z direction). Herein, a vertical level may refer to a height level of an arbitrary component in the vertical direction (the Z direction).

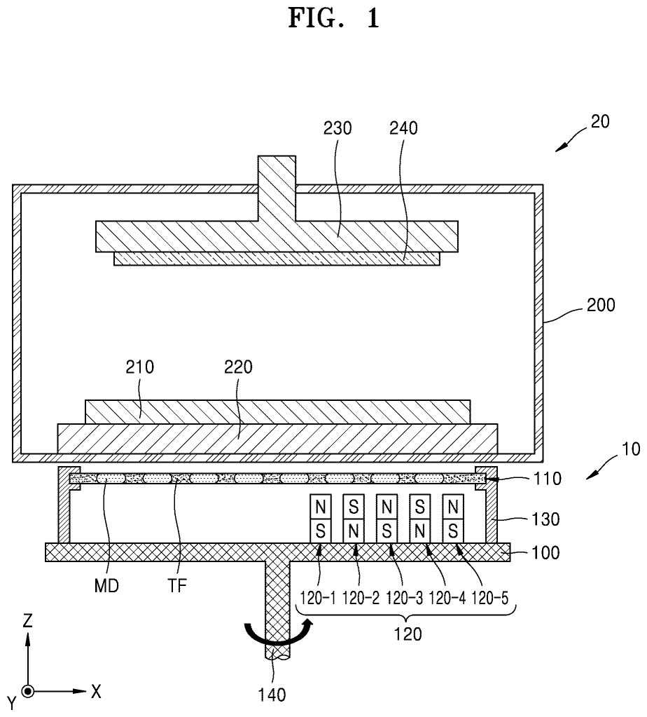

FIG. 1 is a cross-sectional view of an example of a magnetic field generating apparatus.

Referring to FIG. 1, a magnetic field generating apparatus 10 may include a magnet plate 100, a magnetic field shaping pipe 110, a plurality of magnets 120, a support pin 130, and a rotary stage 140.

The magnet plate 100 may include a flat plate. The magnet plate 100 may be arranged behind a sputtering target 210. The magnet plate 100 may include the plurality of magnets 120 arranged on an upper surface of the magnet plate 100. The magnet plate 100 may include a plurality of securing members capable of respectively securing the plurality of magnets 120.

For example, each of the plurality of securing members may include a securing groove. The securing groove may be formed in a shape corresponding to the size and shape of each of the plurality of magnets 120. In addition, each of the plurality of securing members may include various members, such as a securing bracket, an adhesive, a bolt, and a nut, which may secure each of the plurality of magnets 120.

In some implementations, the magnet plate 100 may have a shape corresponding to the shape of the sputtering target 210. For example, when the sputtering target 210 has a circular shape (for example, a cylindrical shape), the magnet plate 100 may have a cylindrical shape. In addition, when the sputtering target 210 has a quadrangular shape (for example, a rectangular parallelepiped shape), the magnet plate 100 may have a rectangular parallelepiped shape. However, the shape of the magnet plate 100, which is described above, is only an example, and the magnet plate 100 may have various shapes.

The magnetic field shaping pipe 110 may be arranged above the magnet plate 100. The magnetic field shaping pipe 110 may be arranged between the sputtering target 210 and the magnet plate 100. The magnetic field shaping pipe 110 may have a certain internal space and may include a transport fluid TF in the internal space of the magnetic field shaping pipe 110. In addition, the magnetic field shaping pipe 110 may include a micro-channel having a horizontal width and a vertical height, which each range from several micrometers (μm) to hundreds of μm. However, the horizontal width and the vertical height of the magnetic field shaping pipe 110 are not limited to the example set forth above and may each range from several millimeters (mm) to tens of mm.

The magnetic field shaping pipe 110 may be arranged apart from the magnet plate 100 by as much as a certain distance in the vertical direction. For example, the magnetic field shaping pipe 110 may be arranged apart from the magnet plate 100 by as much as several mm to tens of mm in the vertical direction.

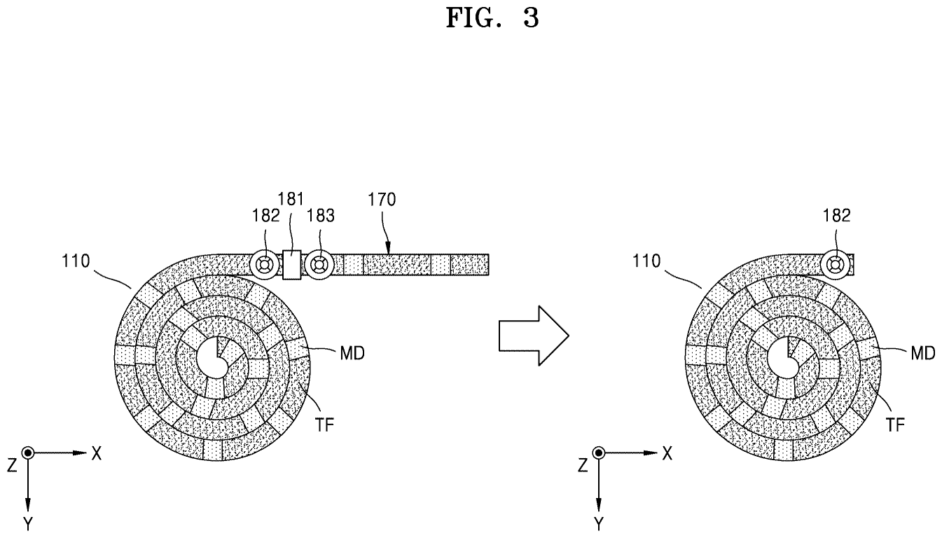

The magnetic field shaping pipe 110 may be implemented in various shapes, based on the shape of the sputtering target 210, the shape of the magnet plate 100, an arrangement structure of the plurality of magnets 120, and the like. As a simplest example, when the sputtering target 210 includes a circular sputtering target and the magnet plate 100 also includes a circular flat plate, the magnetic field shaping pipe 110 may be implemented by a circular spiral pipe, as shown in FIG. 3. However, this is only an example of the shape of the magnetic field shaping pipe 110, and even when the sputtering target 210 includes a circular sputtering target and the magnet plate 100 also includes a circular flat plate, the magnetic field shaping pipe 110 may be implemented in various shapes rather than in the shape of a circular spiral pipe.

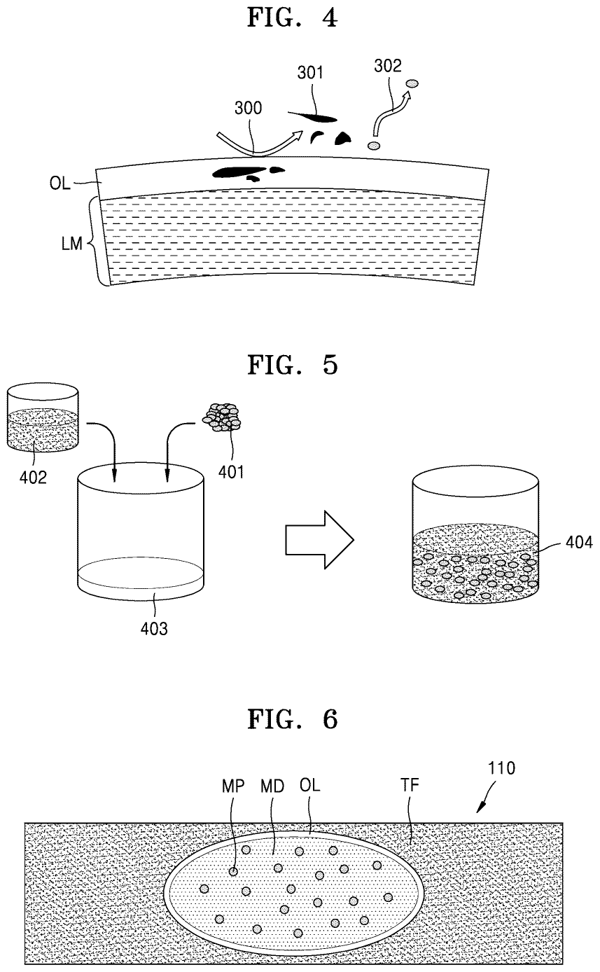

The transport fluid TF may be included in the magnetic field shaping pipe 110 and may include a plurality of magnetic metal droplets MD. A magnetic metal droplet MD may include micro-magnetic particles. When there is an external magnetic field due to the plurality of magnets 120, the micro-magnetic particles may be aligned according to a direction of the external magnetic field. The micro-magnetic particles aligned in the same direction as the direction of the external magnetic field may generate a magnetic field having a new shape. A relatively strong magnetic field may be distributed above the magnetic metal droplet MD, and a relatively weak magnetic field may be distributed above the transport fluid TF in which there is no magnetic metal droplet MD. In other words, the magnetic metal droplet MD may increase the intensity of a magnetic field. The micro-magnetic particles in the magnetic metal droplet MD are described below in detail with reference to FIGS. 4 to 6.

The plurality of magnets 120 may be secured onto the magnet plate 100. The plurality of magnets 120 may be arranged such that N- and S-poles thereof alternately face upwards.

For example, a first magnet 120-1, a third magnet 120-3, and a fifth magnet 120-5 may be arranged such that the respective N-poles thereof face upwards, and a second magnet 120-2 and a fourth magnet 120-4 may be arranged such that the respective S-poles thereof face upwards. In other words, two adjacent magnets may be arranged to respectively have different poles facing upwards.

Each of the plurality of magnets 120 may include a solid-state magnet. For example, each of the plurality of magnets 120 may include a permanent magnet. In this case, each of the plurality of magnets 120 may include samarium cobalt (SmCo), neodymium iron boron (NdFeB), Alnico (AlNiCo), Ferrite, or a combination thereof. As another example, each of the plurality of magnets 120 may include an electromagnet. In this case, each of the plurality of magnets 120 may include a coil through which a current may flow.

Although FIG. 1 illustrates that there are only five magnets 120, this is only an example, and the plurality of magnets 120 may be implemented in various numbers. In addition, although FIG. 1 illustrates that each of the plurality of magnets 120 protrudes from the magnet plate 100 by as much as an equal height, the plurality of magnets 120 may protrude from the magnet plate 100 by as much as respectively different heights, and in this way, the protruding degree of each of the plurality of magnets 120 in an upward direction is not limited to the example shown in FIG. 1.

Although FIG. 1 illustrates that the plurality of magnets 120 may be arranged in a line, this is only an example. The plurality of magnets 120 may be arranged to be radially apart from each other with reference to the center of the magnet plate 100 or may be irregularly arranged, and in this way, the plurality of magnets 120 may be arranged with various structures.

The support pin 130 may be mounted on the magnet plate 100 so as to protrude upwards from the upper surface of the magnet plate 100. The support pin 130 may be configured to support and secure the magnetic field shaping pipe 110. The magnetic field shaping pipe 110 may be separated from the support pin 130.

In some implementations, the support pin 130 may be mounted on an edge portion of the magnet plate 100. In this case, the support pin 130 may support and secure a side portion of the magnetic field shaping pipe 110. The support pin 130 may include a clamp for securing the side portion of the magnetic field shaping pipe 110. In addition, the support pin 130 may be mounted on another portion (for example, the central portion) of the magnet plate 100, and in this way, the support pin 130 may be arranged in various regions in which a portion of the magnetic field shaping pipe 110 may be supported and secured.

Even when the magnet plate 100 is rotated by the rotary stage 140, the support pin 130 may firmly support the magnetic field shaping pipe 110 such that the vertical position of the magnetic field shaping pipe 110 is not changed. The magnetic field shaping pipe 110 may rotate at the same angular velocity as that of the magnet plate 100.

Although FIG. 1 illustrates that the magnetic field shaping pipe 110 may be secured by the support pin 130 mounted on the magnet plate 100, this is only an example. The magnetic field shaping pipe 110 may be coupled to a support member, which protrudes downwards from a lower surface of a plasma chamber housing 200, and thus be supported and secured, and in this way, a method of arranging and securing the magnetic field shaping pipe 110 between the magnet plate 100 and the sputtering target 210 may be based on various configurations and arrangement structures.

The rotary stage 140 may provide rotational force to the magnet plate 100, and the magnet plate 100 may perform a rotational motion in which the magnet plate 100 rotates in a circumferential direction by taking the central axis (Z-direction axis) of the magnet plate 100 as a rotation axis, based on the provided rotational force. As shown in FIG. 1, when the magnetic field shaping pipe 110 is connected to the magnet plate 100 via the support pin 130, the magnetic field shaping pipe 110 may perform a rotational motion at the same angular velocity as that of the magnet plate 100.

Although FIG. 1 illustrates that the magnetic field generating apparatus 10 may be arranged outside the plasma chamber housing 200, this is only an example. The magnetic field generating apparatus 10 may be arranged inside the plasma chamber housing 200, and in this way, the magnetic field generating apparatus 10 may be arranged at various positions.

In addition, although FIG. 1 illustrates that the magnetic field generating apparatus 10 may be arranged under the plasma chamber housing 200, the magnetic field generating apparatus 10 may be arranged on or above the plasma chamber housing 200 or on a lateral side of the plasma chamber housing 200. In this way, the magnetic field generating apparatus 10 may be arranged at various positions so long as the magnetic field generating apparatus 10 may be arranged behind the sputtering target 210 to apply a magnetic field to the sputtering target 210.

A plasma chamber 20 is a chamber in which a plasma treatment process is performed on a substrate 240. Here, the plasma treatment process may include various processes, such as a physical vapor deposition (PVD) process, an etching process, and the like. However, herein, for convenience of description, it is assumed that the plasma chamber 20 corresponds to a chamber in which a PVD process using the sputtering target 210 is performed.

The plasma chamber 20 may include the plasma chamber housing 200, a backing plate 220 on which the sputtering target 210 is arranged, and a substrate supporting plate 230 on which the substrate is arranged.

The plasma chamber housing 200 may define a plasma formation space and may seal the plasma formation space from the outside of the plasma chamber housing 200. In general, the plasma chamber housing 200 may include a metal material and may be connected to a ground potential. The plasma chamber housing 200 may be connected to the ground potential, and thus, may cut off noise from the outside of the plasma chamber housing 200 during a plasma process. An insulating liner may be arranged on an inner side of the plasma chamber housing 200. The insulating liner may protect the plasma chamber housing 200 and may cover metal structures protruding from the plasma chamber housing 200 to prevent the occurrence of arcing or the like. The insulating liner may include ceramic, quartz, or the like.

The backing plate 220 may secure the sputtering target 210. The backing plate 220 may receive a radio-frequency (RF) voltage or a direct-current (DC) voltage from an external power supply. In general, the backing plate 220 may function as a cathode.

The sputtering target 210 may include a raw material to be deposited on the substrate 240. For example, when a material intended to be deposited on the substrate 240 is copper (Cu), the sputtering target 210 may include copper. The sputtering target 210 may be arranged on and secured to an upper surface of the backing plate 220. Cations (for example, argon ions), which are included in plasma formed in the internal space of the plasma chamber housing 200, may collide with the sputtering target 210, and the raw material may be emitted from the sputtering target 210 due to the collision. The emitted raw material may be deposited on the substrate 240.

The substrate supporting plate 230 may secure the substrate 240. The substrate supporting plate 230 may secure the substrate 240 based on electrostatic force and/or mechanical force. In addition, the substrate supporting plate 230 may receive an RF voltage or a DC voltage from the external power supply. In general, the substrate supporting plate 230 may function as an anode.

As described above, the sputtering target 210 emits the raw material based on a sputtering reaction with the plasma formed in the internal space of the plasma chamber housing 200. Therefore, the emission of the raw material may frequently occur in a region in which the density of the plasma is high, and the emission of the raw material may relatively infrequently occur in a region in which the density of the plasma is low. Therefore, while a portion (a portion corresponding to the region having a high density of the plasma) of the sputtering target 210 may be quickly consumed, another portion (a portion corresponding to the region having a low density of the plasma) of the sputtering target 210 may be extremely slowly consumed. Due to the non-uniform erosion of the sputtering target 210 as described above, non-uniform deposition of the raw material on the substrate 240 may occur, or there may be an issue in that the sputtering target 210 needs to be replaced early.

The magnetic field generating apparatus 10 may change the distribution of the plurality of magnetic metal droplets MD in the magnetic field shaping pipe 110 and may apply magnetic fields having various shapes to the internal space of the plasma chamber housing 200. Specifically, according to an erosion distribution of the sputtering target 210, the magnetic field generating apparatus 10 may apply a magnetic field having a shape, which corresponds to the erosion distribution, to the inside of the plasma chamber housing 200, thereby preventing the non-uniform erosion of the sputtering target 210.

For example, when an edge portion of the sputtering target 210 is significantly eroded and the central portion of the sputtering target 210 is hardly eroded, the magnetic field generating apparatus 10 may apply a magnetic field having a shape which allows the density of the plasma in the central space of the plasma chamber housing 200 to be increased and the density of the plasma in the edge space of the plasma chamber housing 200 to be reduced. Specifically, the magnetic field generating apparatus 10 may control the distribution of the magnetic metal droplets MD such that the plurality of magnetic metal droplets MD are densely distributed in the central portion (a position corresponding to the central space of the plasma chamber housing 200) of the magnetic field shaping pipe 110 and are rarely distributed in the edge portion (a position corresponding to the edge space of the plasma chamber housing 200) of the magnetic field shaping pipe 110.

In this case, a strong magnetic field may be applied to the central space of the plasma chamber housing 200, and only a relatively weak magnetic field may be applied to the edge space of the plasma chamber housing 200. Therefore, the density of the plasma in the central space of the plasma chamber housing 200 may be increased, and the density of the plasma in the edge space of the plasma chamber housing 200 may be reduced. The erosion of the sputtering target 210 may frequently occur in the central space having an increased density of the plasma and may slightly occur in the edge space having a reduced density of the plasma.

This is only an example in which the magnetic field generating apparatus 10 controls the distribution of the plurality of magnetic metal droplets MD based on the erosion distribution of the sputtering target 210, and the magnetic field generating apparatus 10 may variously control the distribution of the magnetic metal droplets MD based on the erosion distribution of the sputtering target 210.

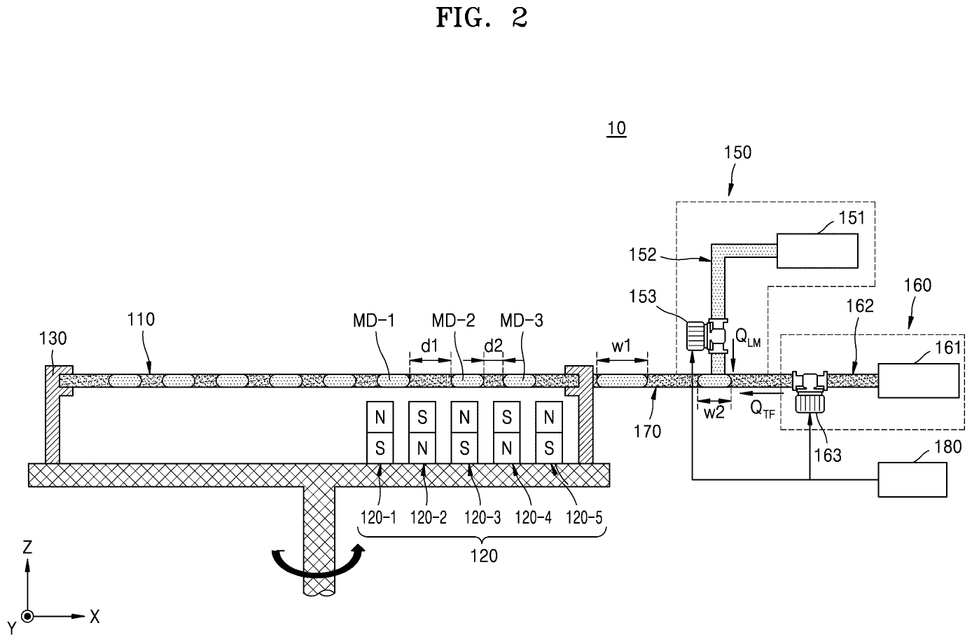

The magnetic field generating apparatus 10 may operate in a magnetic field application mode and in a fluid supply mode. Two operation modes of the magnetic field generating apparatus 10 are described below in detail with reference to FIGS. 2 and 3.

FIG. 2 is a cross-sectional view of an example of a magnetic field generating apparatus.

Referring to FIG. 2, the magnetic field generating apparatus 10 may further include a magnetic liquid metal supply source 150, a transport fluid supply source 160, a supply pipe 170, and a flow-rate control unit 180.

In some implementations, in the fluid supply mode, the magnetic field shaping pipe 110 may receive the transport fluid TF and the plurality of magnetic metal droplets MD from the magnetic liquid metal supply source 150, the transport fluid supply source 160, and the supply pipe 170.

Here, the fluid supply mode may refer to an operation mode for supplying the transport fluid TF and the plurality of magnetic metal droplets MD to the magnetic field shaping pipe 110. In addition, the magnetic field application mode may refer to an operation mode in which the magnetic field generating apparatus 10 applies a magnetic field having a shape intended by a user (for example, a process engineer) to the internal space of the plasma chamber housing 200, and in the magnetic field application mode, there may be plasma in the internal space of the plasma chamber housing 200. In the fluid supply mode, the magnetic field shaping pipe 110 may be connected to the supply pipe 170, and in the magnetic field application mode, the magnetic field shaping pipe 110 may be separated from the supply pipe 170.

The magnetic liquid metal supply source 150 may include a magnetic liquid metal storage tank 151, a magnetic liquid metal conveying pipe 152, and a magnetic liquid metal pump 153.

The magnetic liquid metal storage tank 151 may be a tank for storing a magnetic liquid metal. The magnetic liquid metal storage tank 151 may include a valve for adjusting an output of the magnetic liquid metal and may include a sensor (for example, a liquid level sensor) for measuring a storage amount of the magnetic liquid metal.

The magnetic liquid metal conveying pipe 152 may convey the magnetic liquid metal from the magnetic liquid metal storage tank 151 to the supply pipe 170. The magnetic liquid metal conveying pipe 152 may include a micro-channel having a horizontal width and a vertical height, which each range from several μm to hundreds of μm. However, the horizontal width and the vertical height of the magnetic liquid metal conveying pipe 152 are not limited to the example set forth above and may each range from several mm to tens of mm.

In some implementations, the magnetic liquid metal conveying pipe 152 may form a “T”-shaped connection with the supply pipe 170. Specifically, a connection angle between the magnetic liquid metal conveying pipe 152 and the supply pipe 170 may be 90 degrees. For example, as shown in FIG. 2, the supply pipe 170 may extend lengthwise in the first horizontal direction (the X direction), and the magnetic liquid metal conveying pipe 152 may extend in the vertical direction (the Z direction) and be connected to the supply pipe 170.

In some implementations, the magnetic liquid metal conveying pipe 152 may form a “+”-shaped connection with the supply pipe 170. Specifically, the connection angle between the magnetic liquid metal conveying pipe 152 and the supply pipe 170 may be 90 degrees, the magnetic liquid metal conveying pipe 152 may extend in both directions rather than only in one direction, from the connection point with the supply pipe 170. For example, as shown in FIG. 2, when the supply pipe 170 extends lengthwise in the first horizontal direction (the X direction), the magnetic liquid metal conveying pipe 152 may be implemented by a pipe extending in an upward direction (a +Z direction) and a downward direction (a −Z direction) rather than only in the upward direction (the +Z direction), from the connection point with the supply pipe 170.

However, the connection structure between the magnetic liquid metal conveying pipe 152 and the supply pipe 170, as described above, is only an example, and the magnetic liquid metal conveying pipe 152 and the supply pipe 170 may be connected to each other based on various connection structures that allow the magnetic liquid metal to be transported to the supply pipe 170.

The magnetic liquid metal pump 153 may provide power for conveying the magnetic liquid metal. An inlet valve may be arranged at an entry end of the magnetic liquid metal pump 153, and a discharge valve may be arranged at an exit end of the magnetic liquid metal pump 153. The magnetic liquid metal pump 153 may be implemented by a volumetric pump or a pressure pump.

The magnetic liquid metal pump 153 may adjust the flow rate of the magnetic liquid metal discharged from the magnetic liquid metal pump 153. For example, the flow rate of the magnetic liquid metal discharged from the magnetic liquid metal pump 153 may be adjusted by adjusting the degree of opening of each of the inlet valve and the discharge valve of the magnetic liquid metal pump 153. As another example, the magnetic liquid metal pump 153 may adjust the flow rate of the magnetic liquid metal, which is discharged from the magnetic liquid metal pump 153, by adjusting the volume of a fluid transported by the pump. As yet another example, the magnetic liquid metal pump 153 may adjust the flow rate of the magnetic liquid metal, which is discharged from the magnetic liquid metal pump 153, by adjusting the magnitude of pressure applied to the fluid by the pump.

The transport fluid supply source 160 may include a transport fluid storage tank 161, a transport fluid conveying pipe 162, and a transport fluid pump 163. The transport fluid storage tank 161 may store the transport fluid TF. The transport fluid conveying pipe 162 may convey the transport fluid TF from the transport fluid storage tank 161 to the supply pipe 170. The transport fluid conveying pipe 162 may include a micro-channel. The transport fluid conveying pipe 162 may be connected to the supply pipe 170. In addition, the transport fluid conveying pipe 162 may include a single pipe that is integrated with the supply pipe 170 to form one body.

The transport fluid pump 163 may provide power for conveying the transport fluid TF. An inlet valve may be arranged at an entry end of the transport fluid pump 163, and a discharge valve may be arranged at an exit end of the transport fluid pump 163. The transport fluid pump 163 may be implemented by a volumetric pump or a pressure pump. The transport fluid pump 163 may adjust the flow rate of the transport fluid TF supplied to the supply pipe 170.

The supply pipe 170 may be connected to an entry end of the magnetic field shaping pipe 110 and may supply the transport fluid TF, which includes the plurality of magnetic metal droplets MD therein, to the magnetic field shaping pipe 110.

As shown in FIG. 2, the transport fluid supply source 160 may supply the transport fluid TF in a horizontal direction with respect to the supply pipe 170, and the magnetic liquid metal supply source 150 may supply the magnetic liquid metal in a vertical direction with respect to the supply pipe 170. In this case, the magnetic liquid metal supplied to the connection point between the magnetic liquid metal conveying pipe 152 and the supply pipe 170 may form a magnetic metal droplet MD. Specifically, the magnetic liquid metal supplied to the aforementioned connection point in the vertical direction with respect to the supply pipe 170 may be moved in the horizontal direction by the transport fluid TF, and thus, the magnetic liquid metal having a continuous distribution in the magnetic liquid metal conveying pipe 152 may be separated into magnetic metal droplets MD.

The flow-rate control unit 180 may control the magnetic liquid metal supply source 150 and the transport fluid supply source 160. The flow-rate control unit 180 may be implemented by hardware, firmware, software, or a combination thereof. For example, the flow-rate control unit 180 may include a computing device, such as a workstation computer, a desktop computer, a laptop computer, or a tablet computer. The flow-rate control unit 180 may include a simple controller, a microprocessor, a complex processor, such as a central processing unit (CPU), a graphics processing unit (GPU), or the like, a processor configured by software, dedicated hardware, or firmware. The flow-rate control unit 180 may be implemented by, for example, a general-purpose computer, or application-specific hardware such as a Digital Signal Processor (DSP), a Field-Programmable Gate Array (FPGA), and an Application-Specific Integrated Circuit (ASIC). The flow-rate control unit 180 may be implemented by instructions, which are stored in a machine-readable medium and able to be read and executed by one or more processors. Here, the machine-readable medium may include any mechanism for storing and/or transmitting information in a form readable by a machine (for example, a computing device). For example, the machine-readable medium may include Read-Only Memory (ROM), Random Access Memory (RAM), magnetic disk storage media, optical storage media, flash memory devices, electrical, optical, acoustic or other types of radio signals (for example, carrier waves, infrared signals, digital signals, and the like), and any other signals.

To adjust a magnetic liquid metal supply flow rate Q_{LM} from the magnetic liquid metal supply source 150 to the supply pipe 170, the flow-rate control unit 180 may control the magnetic liquid metal supply source 150. In addition, to adjust a transport fluid supply flow rate Q_{TF} from the transport fluid supply source 160 to the supply pipe 170, the flow-rate control unit 180 may control the transport fluid supply source 160.

In some implementations, the flow-rate control unit 180 may control the magnetic liquid metal pump 153 to adjust the magnetic liquid metal supply flow rate Q_{LM} and may control the transport fluid pump 163 to adjust the transport fluid supply flow rate Q_{TF}. In some implementations, the flow-rate control unit 180 may control a valve of the magnetic liquid metal storage tank 151 to adjust the magnetic liquid metal supply flow rate Q_{LM} and may control a valve of the transport fluid storage tank 161 to control the transport fluid pump 163 to adjust the transport fluid supply flow rate Q_{TF}.

The aforementioned control method by the flow-rate control unit 180 is only an example of controlling a flow rate, and the flow-rate control unit 180 may adjust the magnetic liquid metal supply flow rate Q_{LM} and/or the transport fluid supply flow rate Q_{TF} based on various control methods.

When the magnetic field generating apparatus 10 operates in the fluid supply mode, to adjust an interval between the plurality of magnetic metal droplets MD, the flow-rate control unit 180 may control at least one of the magnetic liquid metal supply source 150 and the transport fluid supply source 160 to adjust a flow rate ratio

$$( that is , \frac{{Q}_{LM}}{{Q}_{TF}} ) .$$

Here, the flow rate ratio

$$( that is , \frac{{Q}_{LM}}{{Q}_{TF}} )$$

may refer to a ratio of the magnetic liquid metal supply flow rate Q_{LM} of the magnetic liquid metal supply source 150 to the transport fluid supply flow rate Q_{TF} of the transport fluid supply source 160. In addition, herein, each of the transport fluid supply flow rate Q_{TF} and the magnetic liquid metal supply flow rate Q_{LM} may be represented by a volumetric flow rate that refers to the volume of a fluid supplied per unit time (that is, ml/min).

In some implementations, the flow-rate control unit 180 may increase the flow rate ratio

$$( that is , \frac{{Q}_{LM}}{{Q}_{TF}} )$$

to reduce the interval between the plurality of magnetic metal droplets MD and may reduce the flow rate ratio

$$( that is , \frac{{Q}_{LM}}{{Q}_{TF}} )$$

to increase the interval between the plurality of magnetic metal droplets MD.

Specifically, the flow-rate control unit 180 may increase the flow rate ratio

$$( that is , \frac{{Q}_{LM}}{{Q}_{TF}} )$$

through a reduction in the transport fluid supply flow rate Q_{TF} and/or an increase in the magnetic liquid metal supply flow rate Q_{LM}. Therefore, the interval between two adjacent magnetic metal droplets MD may be reduced. For example, the flow-rate control unit 180 may increase the flow rate ratio

$$( that is , \frac{{Q}_{LM}}{{Q}_{TF}} )$$

before a time point at which a third magnetic metal droplet MD-3 is generated. Therefore, a second interval d2 between a second magnetic metal droplet MD-2 and the third magnetic metal droplet MD-3 may be less than a first interval d1 between a first magnetic metal droplet MD-1 and the second magnetic metal droplet MD-2.

In some implementations, the flow-rate control unit 180 may reduce the flow rate ratio

$$( that is , \frac{{Q}_{LM}}{{Q}_{TF}} )$$

to reduce the size of each of the plurality of magnetic metal droplets MD and may increase the flow rate ratio

$$( that is , \frac{{Q}_{LM}}{{Q}_{TF}} )$$

to increase the size of each of the plurality of magnetic metal droplets MD.

Specifically, the flow-rate control unit 180 may reduce the flow rate ratio

$$( that is , \frac{{Q}_{LM}}{{Q}_{TF}} )$$

through an increase in the transport fluid supply flow rate Q_{TF} and/or a reduction in the magnetic liquid metal supply flow rate Q_{LM}. Therefore, the size of the magnetic metal droplet MD may be reduced. For example, the flow-rate control unit 180 may reduce the flow rate ratio

$$( that is , \frac{{Q}_{LM}}{{Q}_{TF}} )$$

before a time point at which a fifth magnetic metal droplet MD-5 is generated. Therefore, a second width w2 of the fifth magnetic metal droplet MD-5 may be less than a first width w1 of a fourth magnetic metal droplet MD-4.

As described above, in the fluid supply mode, by adjusting the transport fluid supply flow rate Q_{TF} and/or the magnetic liquid metal supply flow rate Q_{LM}, the flow-rate control unit 180 may control the interval between the plurality of magnetic metal droplets MD supplied to the magnetic field shaping pipe 110 and/or the size of each of the plurality of magnetic metal droplets MD. Through such control, the flow-rate control unit 180 may cause the plurality of magnetic metal droplets MD and the transport fluid TF to be arranged with various distribution shapes in the magnetic field shaping pipe 110.

In addition, although not shown in FIG. 2, each of the magnetic liquid metal supply source 150 and the transport fluid supply source 160 may include various flow sensors, such as a flowmeter and a pressure sensor, which may measure a supply flow rate. A flow sensor may be connected to the flow-rate control unit 180 and may transmit a sensing value of the flow rate to the flow-rate control unit 180.

In addition, although not shown in FIG. 2, according to some implementations, in the fluid supply mode, the magnetic field shaping pipe 110 may be separated from the support pin 130, and then, may receive the transport fluid TF and the plurality of magnetic metal droplets MD.

FIG. 3 is a cross-sectional view of an example of a magnetic field shaping pipe.

Referring to FIG. 3, when the magnetic field generating apparatus 10 operates in the fluid supply mode, the magnetic field shaping pipe 110 may be connected to the supply pipe 170 via a coupling member 181. In addition, when the magnetic field generating apparatus 10 operates in the magnetic field application mode, the magnetic field shaping pipe 110 may be separated from the supply pipe 170.

In some implementations, the magnetic field shaping pipe 110 may include a circular spiral pipe. Specifically, as shown in FIG. 3, the magnetic field shaping pipe 110 may have a spirally wound structure while forming a circular shape from the outside to the inside. However, the structure of the magnetic field shaping pipe 110 shown in FIG. 3 is only an example of the structure of the magnetic field shaping pipe 110. For example, the magnetic field shaping pipe 110 may include a quadrangular spiral pipe or may not have a spiral structure, and in this way, the structure of the magnetic field shaping pipe 110 is not limited to the examples set forth above, and the magnetic field shaping pipe 110 may have various structures.

Specifically, the coupling member 181 may form separable coupling between the magnetic field shaping pipe 110 and the supply pipe 170. The coupling member 181 may have a shape corresponding to sizes and shapes of the magnetic field shaping pipe 110 and the supply pipe 170 and may include a sealing member for preventing the leakage of a fluid or the like. For example, the coupling member 181 may include a component, such as a clamp, a bolt, a nut, a tube, or a joint.

In the fluid supply mode, both an inlet valve 182 of the magnetic field shaping pipe 110 and a discharge valve 183 of the supply pipe 170 may be in an open state. On the other hand, in the magnetic field application mode, both the inlet valve 182 of the magnetic field shaping pipe 110 and the discharge valve 183 of the supply pipe 170 may be in a closed state. Specifically, in the fluid supply mode, when the supply of the transport fluid TF and the plurality of magnetic metal droplets MD to the magnetic field shaping pipe 110 is completed, the inlet valve 182 and the discharge valve 183 are closed, followed by releasing the coupling that is based on the coupling member 181, thereby separating the magnetic field shaping pipe 110 from the supply pipe 170.

In the magnetic field application mode, the transport fluid TF and the plurality of magnetic metal droplets MD within the magnetic field shaping pipe 110 separated from the supply pipe 170 may each be arranged at a stationary position. The transport fluid TF and the plurality of magnetic metal droplets MD, which are each stationary at each position, may generate a magnetic field having a new shape, based on an external magnetic field formed by the plurality of magnets 120.

Although not shown in FIG. 3, in the fluid supply mode, a discharge pipe may be connected to the exit end of the magnetic field shaping pipe 110. Specifically, the discharge pipe may discharge the transport fluid TF and the plurality of magnetic metal droplets MD within the magnetic field shaping pipe 110 to the outside of the magnetic field shaping pipe 110. A user may discharge the transport fluid TF and the plurality of magnetic metal droplets MD to the outside of the magnetic field shaping pipe 110, followed by supplying the transport fluid TF and the plurality of magnetic metal droplets MD again into the magnetic field shaping pipe 110, thereby arranging the magnetic metal droplets MD in a distribution shape, which is intended by the user, in the magnetic field shaping pipe 110.

As described in detail with reference to FIG. 3, the magnetic field shaping pipe 110 may be separably coupled with the supply pipe 170. Therefore, in the magnetic field application mode, the magnetic field generating apparatus 10 may be driven while complex connection structures are minimized. In the following description regarding FIGS. 4 to 6, configurations and characteristics of the transport fluid TF and the magnetic metal droplet MD are described in detail.

FIG. 4 is a diagram illustrating example characteristics of a liquid metal.

Referring to FIG. 4, there may be an oxide layer OL at a surface of a liquid metal LM. Here, the liquid metal LM may refer to a metal material that is present in a liquid state at room temperature. For example, the liquid metal LM may include a gallium-based liquid metal. The gallium-based liquid metal may include gallium (Ga) and may further include metal materials, such as indium (In) and tin (Sn). Herein, descriptions are made by taking only an example in which the liquid metal LM includes a gallium-based liquid metal.

Each of the plurality of magnetic metal droplets MD supplied to the magnetic field shaping pipe 110 may include a gallium-based liquid metal LM and micro-magnetic particles. Specifically, the magnetic metal droplet MD may include a gallium-based magnetic metal droplet MD including micro-magnetic particles therein.

Here, when there is a thick oxide layer OL at the surface of the liquid metal LM, there may be an issue in facilitating the supply of the magnetic metal droplet MD and the transport fluid TF into the magnetic field shaping pipe 110. In addition, due to the presence of the oxide layer OL, the liquid metal LM may not be stably mixed with the micro-magnetic particles.

First, a surface reaction 300 between the oxide layer OL and the transport fluid TF may occur at the surface of the liquid metal LM. Due to the surface reaction 300, residue 301 may be generated, and the residue 301 may be accumulated in a conveying pipe for conveying fluids and may hinder the facilitated supply of fluids. Specifically, the oxide layer OL may include gallium oxide (Ga₂O₃), and the transport fluid TF may generate the residue 301, which includes gallium hydroxide (Ga(OH)₃) and the like, through the surface reaction 300 with gallium oxide.

In addition, when there is the oxide layer OL at the surface of the liquid metal ML, the liquid metal LM may have solid-like flow characteristics. In this case, the magnetic metal droplet MD including the liquid metal LM may not be smoothly conveyed in a pipe, and there may be a phenomenon in which the magnetic metal droplet MD is torn while not maintaining a droplet shape.

Second, when there is the oxide layer OL at the surface of the liquid metal ML, a surface reaction 302 between the oxide layer OL and micro-magnetic particles may occur. For stable mixing between the liquid metal LM and the micro-magnetic particles, a Galvanic reaction between the liquid metal LM and the micro-magnetic particles may need to occur. Here, the Galvanic reaction may refer to an oxidation-reduction reaction occurring between two or more metals. However, due to the surface reaction 302, the micro-magnetic particles are not able to move into the liquid metal ML, and the stable mixing based on the Galvanic reaction is not able to be performed.

To solve such issues due to the presence of the oxide layer OL, the magnetic field generating apparatus 10 may use an acidic aqueous solution or may use the transport fluid TF having low oxygen solubility. This is described below in detail with reference to FIGS. 5 and 6.

FIG. 5 is a diagram illustrating an example of a method of manufacturing a magnetic liquid metal.

Referring to FIG. 5, a magnetic liquid metal 404 may be prepared based on mixing of micro-magnetic particles 401, a liquid metal 402, and an acidic aqueous solution 403.

The micro-magnetic particles 401 may be distributed to be dispersed in the magnetic liquid metal 404. Here, the micro-magnetic particles 401 may each include a ferromagnetic material. For example, the micro-magnetic particles 401 may include iron (Fe), cobalt (Co), nickel (Ni), tungsten (W), or an alloy thereof. Each of the micro-magnetic particles 401 may have a diameter of about 1 μm to about 100 μm. However, the diameter of each of the micro-magnetic particles 401 is not limited to the example set forth above and may be several nm to hundreds of nm.

The micro-magnetic particles 401 distributed in the magnetic liquid metal 404 may be present in an amount of about 5 wt % to about 50 wt % based on the total weight of the magnetic liquid metal 404. Each of the plurality of magnetic metal droplets MD generated based on the supply of the magnetic liquid metal 404 may also include about 5 wt % to about 50 wt % of the micro-magnetic particles 401, based on the weight of the magnetic metal droplet MD.

Here, when the amount of the micro-magnetic particles 401 is greater than 50 wt %, separation between the micro-magnetic particles 401 and the liquid metal 402 may occur in the magnetic metal droplet MD. The separation may occur because an external magnetic field generated by the plurality of magnets 120 causes the micro-magnetic particles 401 to be aligned according to a direction of the external magnetic field. When the separation between the micro-magnetic particles 401 and the liquid metal 402 occurs, the magnetic field generating apparatus 10 may not generate a magnetic field having a shape intended by a user.

In addition, when the amount of the micro-magnetic particles 401 is less than 5 wt %, there may not be a significant effect of strengthening a magnetic field due to the magnetic metal droplet MD. That is, due to the insufficient amount of the micro-magnetic particles 401, the magnetic field generating apparatus 10 may not generate a magnetic field having an intensity intended by a user. Therefore, by using the magnetic metal droplet MD including about 5 wt % to about 50 wt % of the micro-magnetic particles 401, the magnetic field generating apparatus 10 may achieve an effect of generating a magnetic field having a shape and an intensity that are intended by a user.

The acidic aqueous solution 403 may remove the oxide layer OL that is present at the surface of the liquid metal 402. The acidic aqueous solution 403 may correspond to a strong acid having a pH that is less than 3. For example, the acidic aqueous solution 403 may include an aqueous solution of hydrochloric acid, an aqueous solution of sulfuric acid, an aqueous solution of nitric acid, or a combination thereof. When the acidic aqueous solution 403 includes an aqueous solution of hydrochloric acid, gallium oxide constituting the oxide layer OL may be removed based on a reaction shown below.

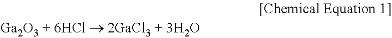

According to Chemical Equation 1, gallium oxide (Ga₂O₃) constituting the oxide layer OL may react with hydrochloric acid (HCl). Thus, gallium oxide (Ga₂O₃) may be removed, and gallium chloride (GaCl₃) may be generated. Therefore, when the liquid metal LM is mixed with the aqueous solution of hydrochloric acid, the oxide layer OL present at the surface of the liquid metal LM may be removed. As the oxide layer OL is removed, the micro-magnetic particles 401 may be stably mixed with the liquid metal LM and may be uniformly distributed in the magnetic liquid metal 404. The magnetic liquid metal 404 prepared based on the mixing method described above may be supplied to the supply pipe 170 and may form the magnetic metal droplet MD.

FIG. 6 is a cross-sectional view illustrating an example of a configuration of the magnetic metal droplet MD.

Referring to FIG. 6, the magnetic metal droplet MD may be conveyed by the transport fluid TF. Micro-magnetic particles MP may be distributed in the magnetic metal droplet MD. The oxygen solubility of the transport fluid TF conveying the magnetic metal droplet MD may have a significant influence on the formation or not of the oxide layer OL.

As described above with reference to FIG. 4, when there is a thick oxide layer OL at the surface of the magnetic metal droplet MD, residue may be generated from the oxide layer OL, and the transport of the magnetic metal droplet MD may not be facilitated. When the transport fluid TF has high oxygen solubility, the oxide layer OL may be prone to be formed at the surface of the magnetic metal droplet MD.

In some implementations, to suppress the generation of the oxide layer OL, the transport fluid TF conveying the magnetic metal droplet MD may have oxygen solubility that is less than 10^{-3.5}. Here, the oxygen solubility of a fluid may refer to the ability of the fluid to dissolve oxygen. Herein, the oxygen solubility may be represented by a mole fraction. For example, when the oxygen solubility of a “fluid A” is 10^{-3.5}, at most 10^{-3.5} mol of oxygen may be dissolved in the “fluid A”.

Specifically, the transport fluid TF may include glycerol, propylene glycol, ethylene glycol, polyethylene glycol, dimethyl sulfoxide (DMSO), or a combination thereof. However, the transport fluid TF is not limited to the examples set forth above and may include various fluids having oxygen solubility that is less than 10^{-3.5}.

Because the oxygen solubility of the transport fluid TF is less than 10^{-3.5}, the oxide layer OL may not be generated at the surface of the magnetic metal droplet MD. In some implementations, although a thin oxide layer OL may be generated at the surface of the magnetic metal droplet MD depending on a value of the oxygen solubility of the transport fluid TF, the oxide layer OL may have a thickness less than 1 nm, and thus, may not hinder the facilitated supply of the magnetic metal droplet MD.

As described above, an oxide layer may not be formed at the surface of the magnetic metal droplet MD. Thus, the micro-magnetic particles MP may be uniformly mixed and distributed in the liquid metal LM, and the magnetic metal droplet MD may be smoothly conveyed by the transport fluid TF.

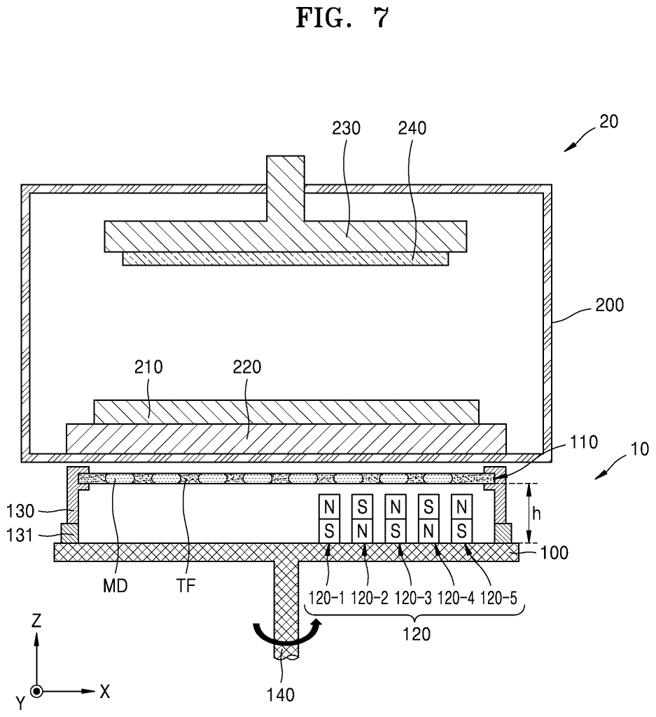

FIG. 7 is a cross-sectional view of an example of a magnetic field generating apparatus.

Regarding FIG. 7, repeated descriptions already given regarding the magnetic field generating apparatus 10 of FIG. 1 are omitted, and the differences from the magnetic field generating apparatus 10 of FIG. 1 are mainly described in detail.

The support pin 130 of the magnetic field generating apparatus 10 may further include an actuator 131. The actuator 131 may adjust a vertical distance h between the magnetic field shaping pipe 110 and the magnet plate 100. In other words, the actuator 131 may adjust a vertical position of the magnetic field shaping pipe 110.

In some implementations, the actuator 131 may adjust the vertical distance h based on the amount of the micro-magnetic particles MP in each of the plurality of magnetic metal droplets MD supplied to the magnetic field shaping pipe 110. Specifically, when the amount of the magnetic metal droplets MD is high, the liquid metal LM and the micro-magnetic particles MP, which are included in the magnetic metal droplet MD, may be separated from each other due to the external magnetic field generated by the plurality of magnets 120. Therefore, the vertical distance h when the amount of the magnetic metal droplets MD is high may be greater than the vertical distance h when the amount of the magnetic metal droplets MD is low.

In some implementations, the actuator 131 may adjust the vertical distance h based on the maximum magnetic flux density of each of the plurality of magnets 120. As described above, because the separation between the liquid metal LM and the micro-magnetic particles MP in the magnetic metal droplets MD occurs due to the external magnetic field generated by the plurality of magnets 120, the vertical distance h may vary in association with the maximum magnetic flux density of each of the plurality of magnets 120. For example, the vertical distance h when the maximum magnetic flux density of each of the plurality of magnets 120 is 4,230 Gauss may be relatively greater than the vertical distance h when the maximum magnetic flux density of each of the plurality of magnets 120 is 1,850 Gauss.

In the above description, an example in which the actuator 131 may adjust the vertical distance h based on the amount of the micro-magnetic particles MP, and an example in which the actuator 131 may adjust the vertical distance h based on the maximum magnetic flux density of each of the plurality of magnets 120 are described separately from each other. However, this is only for convenience of description, and the vertical distance h may vary in association with both the amount of the micro-magnetic particles MP and the maximum magnetic flux density of each of the plurality of magnets 120.

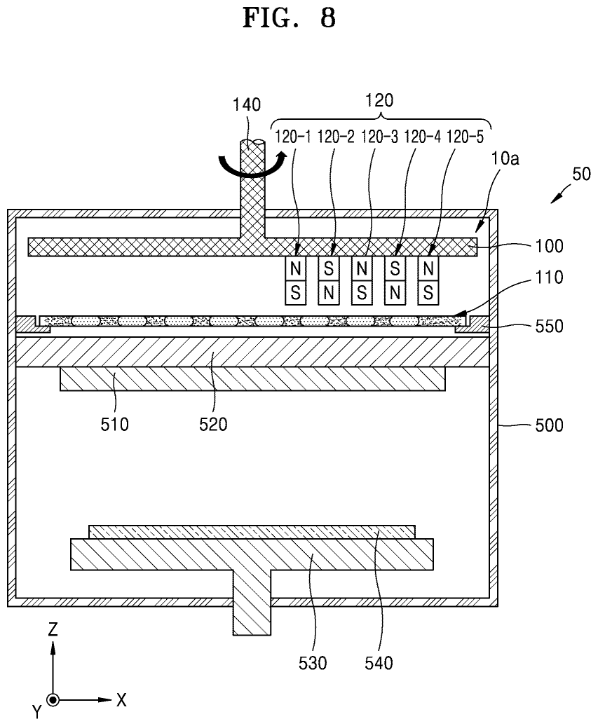

FIG. 8 is a cross-sectional view of an example of a magnetic field generating apparatus.

Regarding FIG. 8, repeated descriptions already given regarding the magnetic field generating apparatus 10 of FIG. 1 and FIG. 7 are omitted, and the differences from the magnetic field generating apparatus 10 of FIGS. 1 and 7 are mainly described in detail.

Referring to FIG. 8, a magnetic field generating apparatus 10a may be arranged in a plasma chamber housing 500. In addition, the magnetic field generating apparatus 10a may be arranged above a space in which plasma is formed.

A plasma chamber 50 may include the plasma chamber housing 500, a backing plate 520 on which a sputtering target 510 is arranged, and a substrate supporting plate 530 on which a substrate is arranged.

In addition, the magnetic field shaping pipe 110 of the magnetic field generating apparatus 10a may be arranged to be secured to a mount 550 that is mounted on an inner wall of the plasma chamber housing 500. In some implementations, in the fluid supply mode, the magnetic field shaping pipe 110 may be separated from the mount 550 and moved outside the plasma chamber housing 500, and the supply of the plurality of magnetic metal droplets MD and the transport fluid TF to the magnetic field shaping pipe 110 may be performed outside the plasma chamber housing 500.

In some implementations, in the fluid supply mode, the magnetic field shaping pipe 110 may be connected to the supply pipe 170 that extends in the horizontal direction through a sidewall of the plasma chamber housing 500. In this case, the plurality of magnetic metal droplets MD and the transport fluid TF may be supplied to the magnetic field shaping pipe 110 from the supply pipe 170 that is connected to the magnetic field shaping pipe 110 through the sidewall of the plasma chamber housing 500.

As described above, the magnetic field generating apparatus 10 includes the magnetic field shaping pipe 110 in which the plurality of magnetic metal droplets MD are arranged, and thus, the magnetic field generating apparatus 10 may generate magnetic fields having various shapes and may apply the magnetic fields having various shapes to the internal space of a plasma chamber housing. Therefore, the magnetic field generating apparatus 10 may prevent non-uniform erosion of a sputtering target.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to implementations thereof, it will be understood that various changes in form and details may be made therein without departing from the spirit and scope of the following claims.

What is claimed is:

1. A magnetic field generating apparatus comprising:
a magnet plate comprising a plurality of magnets positioned on an upper surface of the magnet plate; and
a magnetic field shaping pipe positioned above the magnet plate,
wherein the magnetic field shaping pipe is configured to receive a transport fluid,
wherein a plurality of magnetic metal droplets are positioned in the transport fluid,
wherein the plurality of magnetic metal droplets are spaced apart from each other in a horizontal direction,
wherein each magnetic metal droplet of the plurality of magnetic metal droplets comprises a plurality of micro-magnetic particles, and
wherein N-poles and S-poles of the plurality of magnets are configured to alternately face upwards.

2. The magnetic field generating apparatus of claim 1, wherein the transport fluid has oxygen solubility that is less than 10^{-3.5}.

3. The magnetic field generating apparatus of claim 2, wherein the transport fluid comprises at least one of glycerol, propylene glycol, ethylene glycol, polyethylene glycol, or dimethyl sulfoxide.

4. The magnetic field generating apparatus of claim 1, wherein each magnetic metal droplet of the plurality of magnetic metal droplets comprises a gallium-based liquid metal,
wherein the plurality of micro-magnetic particles comprise a ferromagnetic material, and
wherein each micro-magnetic particle of the plurality of micro-magnetic particles has a diameter of 1 μm to 100 μm.

5. The magnetic field generating apparatus of claim 4, wherein each magnetic metal droplet of the plurality of magnetic metal droplets includes the gallium-based liquid metal, the ferromagnetic material, and an acidic aqueous solution, and
wherein the acidic aqueous solution has a pH that is less than 3.

6. The magnetic field generating apparatus of claim 4, wherein the ferromagnetic material is present in an amount of 5 wt % to 50 wt % in a magnetic metal droplet of the plurality of magnetic metal droplets based on a weight of the magnetic metal droplet.

7. The magnetic field generating apparatus of claim 1, comprising:
a supply pipe configured to be coupled to an entry end of the magnetic field shaping pipe and configured to supply the transport fluid into the magnetic field shaping pipe;
a transport fluid supply source connected with the supply pipe and configured to supply the transport fluid into the supply pipe;
a magnetic liquid metal supply source connected with the supply pipe and configured to supply the plurality of magnetic metal droplets into the supply pipe; and
a flow-rate control circuit configured to control the transport fluid supply source and the magnetic liquid metal supply source.

8. The magnetic field generating apparatus of claim 7, wherein the flow-rate control circuit is configured to, in a fluid supply mode, control at least one of the transport fluid supply source or the magnetic liquid metal supply source to adjust a flow rate ratio to thereby adjust at least one of an interval between the plurality of magnetic metal droplets or a size of each magnetic metal droplet of the plurality of magnetic metal droplets,
wherein, in the fluid supply mode, the transport fluid and the plurality of magnetic metal droplets are configured to be supplied into the magnetic field shaping pipe, and
wherein the flow rate ratio is a ratio of a supply flow rate of the magnetic liquid metal supply source to a supply flow rate of the transport fluid supply source.

9. The magnetic field generating apparatus of claim 8, wherein, in the fluid supply mode, the flow-rate control circuit is configured to:
increase the flow rate ratio to reduce the interval between the plurality of magnetic metal droplets; and
reduce the flow rate ratio to increase the interval between the plurality of magnetic metal droplets.

10. The magnetic field generating apparatus of claim 8, wherein, in the fluid supply mode, the flow-rate control circuit is configured to:
reduce the flow rate ratio to reduce the size of each magnetic metal droplet of the plurality of magnetic metal droplets; and
increase the flow rate ratio to increase the size of each magnetic metal droplet of the plurality of magnetic metal droplets.

11. The magnetic field generating apparatus of claim 7, comprising a rotary stage configured to, in a magnetic field application mode, rotate the magnet plate in a circumferential direction with reference to a central axis of the magnet plate,
wherein the magnetic field shaping pipe is separated from the supply pipe in the magnetic field application mode.

12. A magnetic field generating apparatus comprising:
a magnet plate positioned behind a sputtering target and comprising a plurality of magnets that are positioned on an upper surface of the magnet plate; and
a magnetic field shaping pipe positioned between the magnet plate and the sputtering target,
wherein the magnetic field shaping pipe is configured to receive a transport fluid,
wherein a plurality of magnetic metal droplets are positioned in the transport fluid,
wherein the plurality of magnetic metal droplets are spaced apart from each other in a horizontal direction,
wherein each magnetic metal droplet of the plurality of magnetic metal droplets comprises a plurality of micro-magnetic particles, and
wherein N-poles and S-poles of the plurality of magnets are configured to alternately face upwards.

13. The magnetic field generating apparatus of claim 12, wherein the transport fluid has oxygen solubility that is less than 10^{-3.5}.

14. The magnetic field generating apparatus of claim 13, wherein the transport fluid comprises at least one of glycerol, propylene glycol, ethylene glycol, polyethylene glycol, or dimethyl sulfoxide.

15. The magnetic field generating apparatus of claim 12, wherein each magnetic metal droplet of the plurality of magnetic metal droplets comprises a gallium-based liquid metal,
wherein the plurality of micro-magnetic particles comprise a ferromagnetic material, and
wherein each micro-magnetic particle of the plurality of micro-magnetic particles has a diameter of 1 μm to 100 μm.

16. The magnetic field generating apparatus of claim 15, wherein each magnetic metal droplet of the plurality of magnetic metal droplets includes the gallium-based liquid metal, the ferromagnetic material, and an acidic aqueous solution, and
wherein the acidic aqueous solution has a pH that is less than 3.

17. The magnetic field generating apparatus of claim 12, comprising:
a supply pipe configured to be coupled to an entry end of the magnetic field shaping pipe and configured to supply the transport fluid into the magnetic field shaping pipe;
a transport fluid supply source connected with the supply pipe and configured to supply the transport fluid into the supply pipe;
a magnetic liquid metal supply source connected with the supply pipe and configured to supply the plurality of magnetic metal droplets into the supply pipe; and
a flow-rate control circuit configured to control the transport fluid supply source and the magnetic liquid metal supply source.

18. The magnetic field generating apparatus of claim 17, comprising a rotary stage configured to, in a magnetic field application mode, rotate the magnet plate in a circumferential direction with reference to a central axis of the magnet plate,
wherein the magnetic field shaping pipe is separated from the supply pipe in the magnetic field application mode.

19. A magnetic field generating apparatus comprising:
a magnet plate positioned behind a sputtering target and comprising a plurality of magnets that are positioned on an upper surface of the magnet plate;
a magnetic field shaping pipe positioned between the magnet plate and the sputtering target; and
a support pin protruding from the upper surface of the magnet plate and connected with a portion of the magnetic field shaping pipe to support the magnetic field shaping pipe,
wherein the magnetic field shaping pipe is configured to receive a transport fluid,
wherein a plurality of magnetic metal droplets are positioned in the transport fluid,
wherein the plurality of magnetic metal droplets are spaced apart from each other in a horizontal direction,
wherein each magnetic metal droplet of the plurality of magnetic metal droplets comprises a plurality of micro-magnetic particles, and
wherein N-poles and S-poles of the plurality of magnets are configured to alternately face upwards.

20. The magnetic field generating apparatus of claim 19, comprising an actuator configured to adjust a vertical position of the magnetic field shaping pipe to thereby adjust a vertical distance between the magnetic field shaping pipe and the magnet plate,
wherein the vertical distance between the magnetic field shaping pipe and the magnet plate varies in association with an amount of the plurality of micro-magnetic particles of each magnetic metal droplet of the plurality of magnetic metal droplets.
